(19) United States
(12) Patent Application Publication
(10) Pub. No.: US 2024/0098911 A1
(43) Pub. Date: Mar. 21, 2024

(54) FLEXIBLE INSULATION DISPLACEMENT TERMINAL

(71) Applicant: VEONEER US SAFETY SYSTEMS, LLC, Southfield, MI (US)

(72) Inventor: Jacob Jay Yoder, Dundee, MI (US)

(21) Appl. No.: 17/949,373

(22) Filed: Sep. 21, 2022

(51) Int. Cl. H05K 5/00; H01R 4/2429

(52) U.S. Cl. CPC H05K 5/0069; H01R 4/2429

(57) ABSTRACT

An insulation displacement terminal comprises a first portion, a second portion, and a press-fit pin. The first portion may comprise a first beam and a second beam. A slot is generally formed by a first central edge of the first beam and a second central edge of the second beam. The second portion may comprise a third beam, a fourth beam, and a fifth beam. The fourth beam is configured as a cantilever beam with an attached lower end and a distal end that is able to move between the third beam and the fifth beam. The press-fit pin is generally attached to an edge of the distal end of the fourth beam.

### FIELD OF THE INVENTION

The invention relates to electrical connections generally and, more particularly, to a method and/or apparatus for implementing a flexible insulation displacement terminal.

### BACKGROUND

A common method used to connect a component (e.g., a capacitor) to a circuit board is through the use of an insulation displacement terminal (IDT). In an electronic module, the capacitor is commonly attached to a housing and a fork shaped feature of the IDT is pressed onto a lead of the capacitor. A press-fit pin feature on the other side of the IDT is pressed through a hole (e.g., plated via) in the circuit board to complete the electrical connection between the capacitor and the circuit board. In electronic modules, a connector is also commonly attached to the circuit board.

In modules where performance during vibration is important (e.g., airbag control modules), the IDT is rigidly attached to the housing with an interference fit. An interference fit, also known as a pressed fit or friction fit, is a form of fastening between two tight fitting mating parts that produces a joint which is held together by friction after the parts are pushed together. In these modules the connector also needs to be rigidly attached to the housing with an interference fit. When more than one location of the circuit board is constrained to the housing in the same axis, tolerance stack-up becomes absorbed by the IDT in the form of deformation and possibly fracture.

It would be desirable to implement a flexible insulation displacement terminal.

### SUMMARY

The invention concerns an insulation displacement terminal comprising a first portion, a second portion, and a press-fit pin. The first portion may comprise a first beam and a second beam. A slot is generally formed by a first central edge of the first beam and a second central edge of the second beam. The second portion may comprise a third beam, a fourth beam, and a fifth beam. The fourth beam is configured as a cantilever beam with an attached lower end and a distal end that is able to move between the third beam and the fifth beam. The press-fit pin is generally attached to an edge of the distal end of the fourth beam.

### BRIEF DESCRIPTION OF THE FIGURES

Embodiments of the invention will be apparent from the following detailed description and the appended claims and drawings.

FIG. 1 is a diagram is a perspective view of an electronic control module illustrating a context of the invention.

FIG. 2 is a diagram illustrating an exploded view of the electronic control module of FIG. 1.

FIG. 3 is a diagram illustrating flexible insulation displacement terminals in accordance with an example embodiment of the invention connected to a component inserted in an upper housing of the electronic control module of FIG. 1.

FIG. 4 is a diagram illustrating the component inserted in the upper housing of FIG. 3 prior to insertion of the flexible insulation displacement terminals.

FIG. 5 is a diagram illustrating a flexible insulation displacement terminal in accordance with an example embodiment of the invention.

FIG. 6 is a diagram illustrating a flexible insulation displacement terminal in accordance with an example embodiment of the invention inserted in a printed circuit board.

FIG. 7 is a diagram illustrating another example of a component connected to flexible insulation displacement terminals in accordance with an example embodiment of the invention.

FIG. 8 is a diagram illustrating an application of the flexible insulation displacement terminals in accordance with an example embodiment of the invention.

FIG. 9 is a diagram illustrating a method of assembling an electronic control unit including flexible insulation displacement terminals in accordance with an example embodiment of the invention.

### DETAILED DESCRIPTION OF THE EMBODIMENTS

Embodiments of the present invention include providing a flexible insulation displacement terminal that may (i) allow a portion of an insulation displacement terminal to flex by having a press-fit pin geometry located on a distal end of a cantilever beam, (ii) allow some tolerance stack-up to be absorbed, (iii) reduce stress on a compliant zone of the press-fit pin, (iv) allow part of the insulation displacement terminal to stay rigidly attached to the housing while the cantilever beam section is able to move with a circuit board, (v) allow a coining operation to be performed towards an attached lower end of the cantilever beam to reduce deflection force and stress, (vi) reduce material from the cantilever beam by skiving or milling to reduce deflection force and stress, and/or (vi) be implemented in an electronic control module.

In various embodiments, an flexible insulation displacement terminal (IDT) is provided that may have a press-fit pin geometry located on a distal end of a cantilever beam. The cantilever beam generally allows some tolerance to be absorbed, reducing stress on a compliant zone of the press-fit pin. In various embodiments, part of the flexible IDT remains rigidly attached to a housing while the cantilever beam section may move with an attached circuit board. In an example, a coining operation may be performed towards an attached lower end of the cantilever beam to reduce deflection force and stress. In another example, material may also be reduced from the cantilever beam (e.g., by skiving or milling) to reduce deflection force and stress.

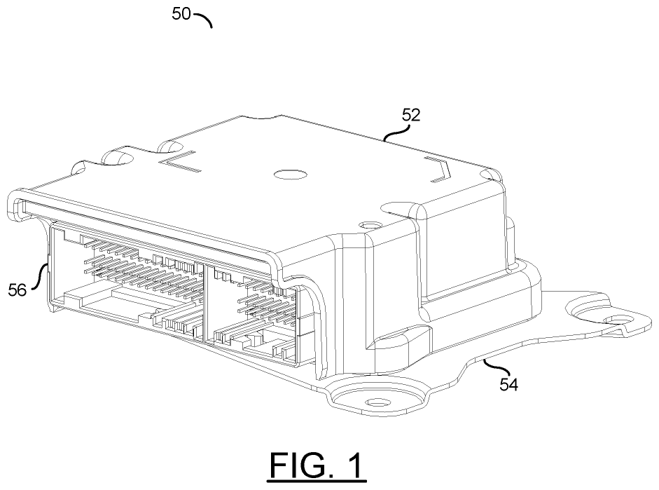

Referring to FIG. 1, a diagram is shown illustrating a perspective view of an electronic control module illustrating a context of the invention. In various embodiments, an apparatus 50 may implement an electronic control unit (or module). In an example, the apparatus 50 may implement a restraint control system (RCS) electronic control unit (ECU). The apparatus 50 generally comprises an upper housing 52, a lower housing (or cover or baseplate) 54 and a subassembly 56.

The upper housing 52 may be implemented as a non-conductive enclosure. In some embodiments, the upper housing 52 may be configured to provide an environmentally sealed enclosure while mated with the lower housing 54 and the subassembly 56. The upper housing 52 may protect components and devices of the subassembly 56. In an example, the upper housing 52 may be formed of a plastic or resin-based material. In various embodiments, the plastic or resin-based material may include, but is not limited to polyamide (NYLON), polybutylene terephthalate (PBT), polypropylene, polyethylene terephthalate (PET), acrylonitrile butadiene styrene (ABS), and/or various alloys and/or fillers of the resins. However, other materials may be implemented to meet the design criteria of a particular application. In various embodiments, the upper housing 52 may be formed using various techniques including, but not limited to, casting, injection molding, and three-dimensional printing.

The lower housing 54 may be implemented as an electrically conductive baseplate. The lower housing 54 is generally configured to provide mechanical support, thermal cooling, and electrical grounding for the apparatus 50. In various embodiments, the lower housing 54 may comprise a die-cast Aluminum baseplate. In another example, the baseplate 54 may be implemented as a stamped steel baseplate. Implementing the baseplate 54 with a metallic material may aid in dissipating heat generated by circuitry within the apparatus 50. The baseplate 54 is generally configured to provide a mounting footprint for the apparatus 50. In an example, the baseplate 54 may be implemented with an RCM8 mounting footprint to simplify testing. However, other footprints may be implemented to meet the design criteria of a particular application.

The subassembly (or electrical assembly) 56 may implement an electronic component of the apparatus 50. The subassembly 56 may be operational to perform one or more electrical functions. The electrical functions may include, but are not limited to, providing grounding paths for all electrical components inside the apparatus 50 to the exterior of the apparatus 50, transfer electrical inputs from different circuits in a vehicle to electronic components mounted inside the apparatus 50, monitor the performance of electronic sensors in the vehicle, and/or transmit acceleration changes in the vehicle to the electronic components mounted in the apparatus 50. In various embodiments, the subassembly 56 generally comprises a plate having one or more integrated connectors attached to one or more printed circuit boards (PCBs). The plate may be shaped to form a fifth side of the apparatus 50 while secured to the upper housing 52. The one or more printed circuit boards may contain electrical circuitry configured to perform the electrical functions. In various embodiments, electronic components mounted in the upper housing 52 of the apparatus 50 may be connected to the subassembly 56 by flexible insulation displacement terminals in accordance with an embodiment of the invention.

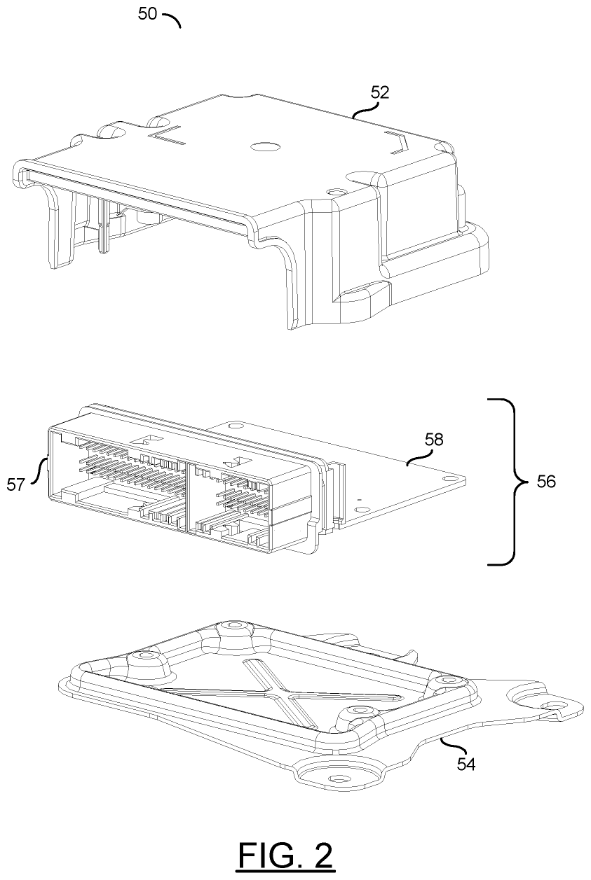

Referring to FIG. 2, a diagram is shown illustrating an exploded view of the electronic control module 50 of FIG. 1. In an example, assembly of the electronic control module 50 may comprise assembling the subassembly 56 by attaching a connector assembly 57 to a circuit board assembly 58, attaching the circuit board assembly 58 with the attached connector assembly 57 to the upper housing 52, and assembling the lower housing 54 to the upper housing 52 (e.g., using threaded fasteners, etc.). In some embodiments, a gasket or sealant material (not shown) may be applied between one or more of the upper housing 52, the lower housing 54, and the subassembly 56. In some embodiments, welding or fusing may be performed to seal the connector assembly 57 of the subassembly 56 to the upper housing 52.

In an example, an assembly process for the subassembly 56 may comprise a number of steps. In an example, a raw terminal carrier may be fed to a stitching station. The stitching station may stitch a row of terminal pins into the raw carrier. The stitching station may then pass the stitched carrier to a form station, where the form station forms an appropriate (e.g., 90 degrees, etc.) bend for the current row. The stitching and forming processes may be repeated until a number or rows of terminal pins desired have been stitched and formed to produced a completed terminal carrier assembly. The completed terminal carrier assembly may then be assembled to a connector shroud to form the connector assembly 57. The connector assembly 57 may then be assembled to a printed circuit board substrate of the circuit board assembly 58 to form the subassembly 56.

In various embodiments, the terminal carrier generally includes a feature on each side (end) of the terminal carrier. The features are generally configured to align the terminal carrier with an interior surface of sides of the upper housing 52. In various embodiments, a profile of the connector assembly 57 and the features may be configured to align the circuit board assembly 58 within the upper housing 52. In various embodiments, the circuit board assembly 58 may include vias that are also aligned with press-fit pins of flexible IDTs inserted in the upper housing 52. In various embodiments, a press fit connection is formed between the circuit board assembly 58 and the flexible IDTs in the upper housing 52 as the subassembly 56 is assembled to the upper housing 52.

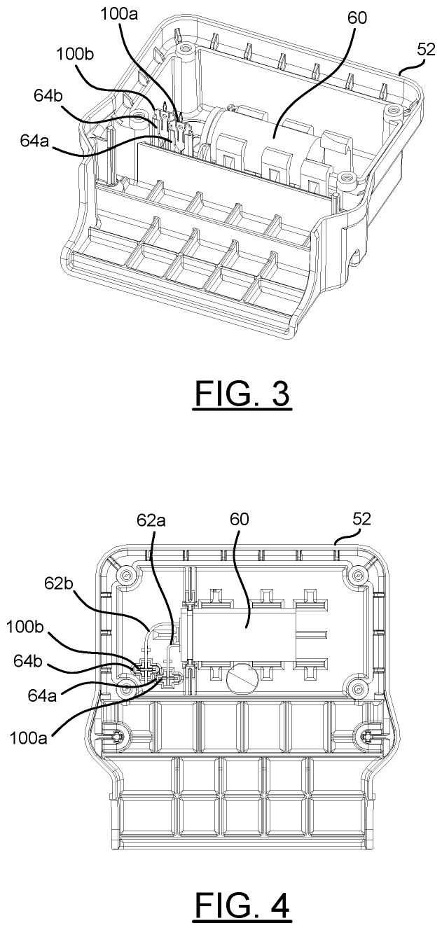

Referring to FIG. 3, a diagram is shown illustrating an interior of the apparatus upper housing 52 of FIG. 2 with a component 60 and flexible insulation displacement terminals (IDTs) 100a and 100b installed. In an example, the electronic component 60 may comprise a charge storage device. In an example, the electronic component 60 may comprise a capacitor. By using the flexible IDTs 100a and 100b, leads of the component 60 are generally enabled to be connected to the circuit board assembly 58 when the subassembly 56 is installed in the upper housing 52.

Referring to FIG. 4, a diagram of plan view of the interior of the upper housing 52 is shown illustrating the electronic component 60 placed on a component cradle integrally formed within the upper housing 52. In an example, the electronic component 60 may be biased toward one end of the component cradle. However, other arrangements may be implemented to meet design criteria of a particular application. In an example, the component cradle may limit (or prevent) the electronic component 60 from moving along an axial direction, limiting (or preventing) stress from being placed on leads 62a and 62b of the electronic component 60. The leads 62a and 62b are shown formed in a ninety degree bend and inserted in terminal support features 64a and 64b, respectively. The terminal support features 64a and 64b are generally configured to receive and rigidly hold the flexible IDTs 100a and 100b, respectively. In an example, the flexible IDTs 100a and 100b, when inserted in the terminal support features 64a and 64b, make secure electrical connections with the leads 62a and 62b, respectively. In an example, the terminal support features 64a and 64b are generally positioned to align an axis along which the flexible IDTs 100a and 100b are configured to flex in an orientation to absorb stresses created during assembly.

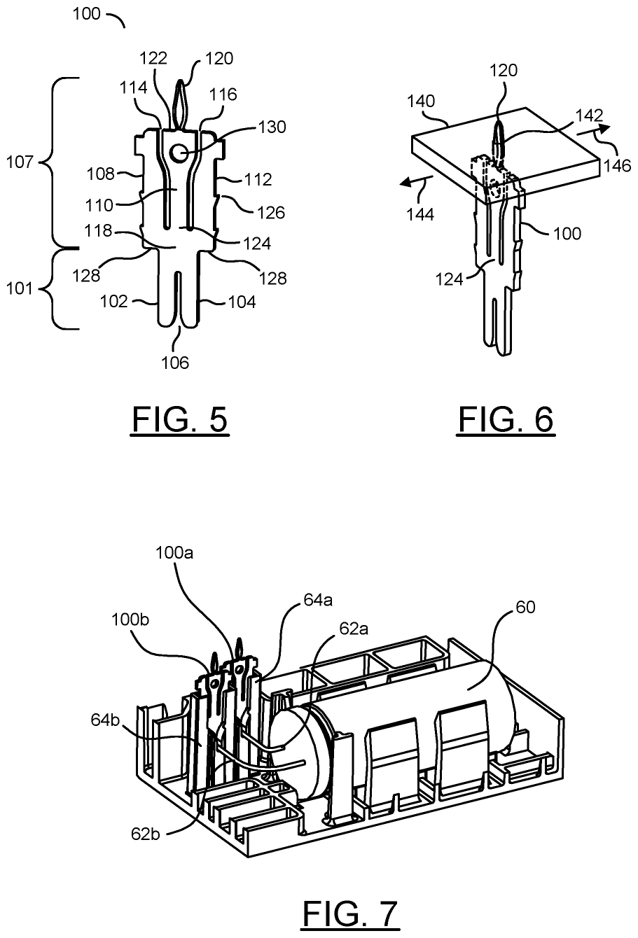

Referring to FIG. 5, a diagram is shown illustrating a flexible insulation displacement terminal in accordance with an example embodiment of the invention. In an example, a flexible insulation displacement terminal (IDT) 100 in accordance with an example embodiment of the invention may comprise a metal plate. In an example, the metal plate may comprise a base material and a plating material. In an example, the base material may include, but is not limited to, various copper alloys (e.g., tin, nickel, zinc, silicon, silver, iron, titanium, chromium). In an example, the plating material may include, but is not limited to, tin, nickel, silver, and zinc. The flexible IDT 100 generally has a rectangular shape that is longer in an up and down direction as shown in FIG. 5. In an example, the flexible IDT 100 may be implemented having an overall height of approximately 22 mm. In various embodiments, the flexible IDT 100 may be implemented having a various material thicknesses (e.g., approximately 0.4 mm, 0.64 mm, 0.8 mm, 1.2 mm, etc.).

In various embodiments, a first (lower) portion 101 of the flexible IDT 100 has a first beam 102 and a second beam 104. A slot 106 is formed by a first central edge of the beam 102 and a second central edge of the beam 104. The first central edge of the beam 102 and the second central edge of the beam 104 are generally configured to form a connection to a wire or lead as the slot 106 is pushed onto the wire or lead. The slot 106 is generally open at a lower end of the first portion 101 and extends upward. An inner end of the slot 106 generally has a rounded semicircular shape. In an example, the beam 102 and the beam 104 may have an approximate width of 1.5 mm. In an example, the slot 106 may be implemented having a width that is smaller than a corresponding width (or diameter) of the component lead (or wire) to be received. In an example, for component lead diameters such as 0.8 mm and 1.0 mm, the slot 106 of the flexible IDT 100 may have approximate widths of about 0.52 mm and 0.7 mm, respectively.

A second (upper) portion 107 of the flexible IDT 100 generally comprises a third beam 108, a fourth beam 110, and a fifth beam 112. A slot 114 is formed by a left edge of the beam 108 and a right edge of the beam 110. A slot 116 is formed by a left edge of the beam 110 and a right edge of the beam 112. A lower end of the second portion 107 of the flexible IDT 100 and an upper end of the first portion 101 of the flexible IDT 100 are generally connected and form a central portion 118. The first portion 101 of the flexible IDT 100 is generally narrower than the second portion 107 of the flexible IDT 100. A press-fit pin 120 is generally attached to an upper edge of a distal end 122 of the beam 110. In an example, the press-fit pin 120 may be configured to fit various printed circuit board hole (or via) sizes (e.g., approximately 0.6 mm, 1.05 mm, 1.5 mm, 2.05 mm). In an example, the size of the printed circuit board hole (or via) the press-fit pin 120 is configured to fit may correspond to the material thickness of the flexible IDT 100.

In an example, the slots 114 and 116 are generally curved such that the upper edge of the distal end 122 of the beam 110 is generally wider than an attached lower (proximate) end 124 of the beam 110. In an example, the beams 108, 110, and 112 may have approximate widths that vary from 1.5-2.0 mm. The beam 110 generally implements a cantilevered beam of the flexible IDT 100. The beam 110 may move (deflect) between the third beam 108 and the fifth beam 112, elastically bending at the attached lower end 124 connecting the beam 110 to the central portion 118 of the flexible IDT 100. In an example, outer edges of the second portion 107 generally include a right edge of the beam 108 and a left edge of the beam 112. In an example, the outer edges of the second portion 107 may comprise a plurality of barb features 126. In an example, the barb features 126 may allow the flexible IDT 100 to rigidly attach (e.g., by an interference fit) to a corresponding one of the terminal support features 64a-64b within the upper housing 52 of the electronic control module 50. In an example, the outer edges of the second portion 107 may form a plurality of shoulder features 128 at the central portion 118. In an example, the shoulder features 128 may provide an installation stop. In an example, the shoulder features 128 may allow the flexible IDT 100 to be inserted to a predetermined depth into a corresponding one of the terminal support features 64a-64b within the upper housing 52 of the electronic control module 50. In an example, an automated assembly tool may be configured to insert the flexible IDT 100 to the predetermined depth into the corresponding one of the terminal support features 64a-64b within the upper housing 52 of the electronic control module 50.

In an example, the beam 110 may include one or more optional holes 130 adjacent to the upper edge of the distal end 122 of the beam 110. In an example, the optional one or more holes 130 may be utilized in an assembly process to grab (or locate) the flexible IDT 100 to insert the flexible IDT 100 into and/or align the flexible IDT 100 to terminal support features 64a-64n in an upper housing 52. In another example, the optional one or more holes 130 may be utilized as an indicator feature. In an example, one hole 130 may indicate the flexible IDT 100 is to be used with a 0.8 mm diameter lead. In another example, two holes 130 may indicate the flexible IDT 100 is to be used with a 1.0 mm diameter lead.

Referring to FIG. 6, a diagram is shown illustrating a flexible insulation displacement terminal in accordance with an example embodiment of the invention inserted in a printed circuit board. In an example, the press-fit pin 120 connects the flexible IDT 100 to a circuit board 140 by the press-fit pin 120 being pressed into a via 142 of the printed circuit board 140. In an example, the flexible IDT 100 generally has an axis along which the cantilever beam 110 of the flexible IDT 100 may flex or deflect (e.g., illustrated by arrows 144 and 136). In various embodiments, the cantilever beam 110 of the flexible IDT 100 generally flexes in a direction perpendicular to a plane of the flexible IDT 100 (e.g., as illustrated by arrows 144 and 146). In an example, a coining operation may be performed towards the attached lower end 124 of the cantilever beam 110 to reduce deflection force and/or stress. In another example, material may also be reduced (or removed) from the cantilever beam 110 (e.g., by skiving or milling) to reduce deflection force and/or stress.

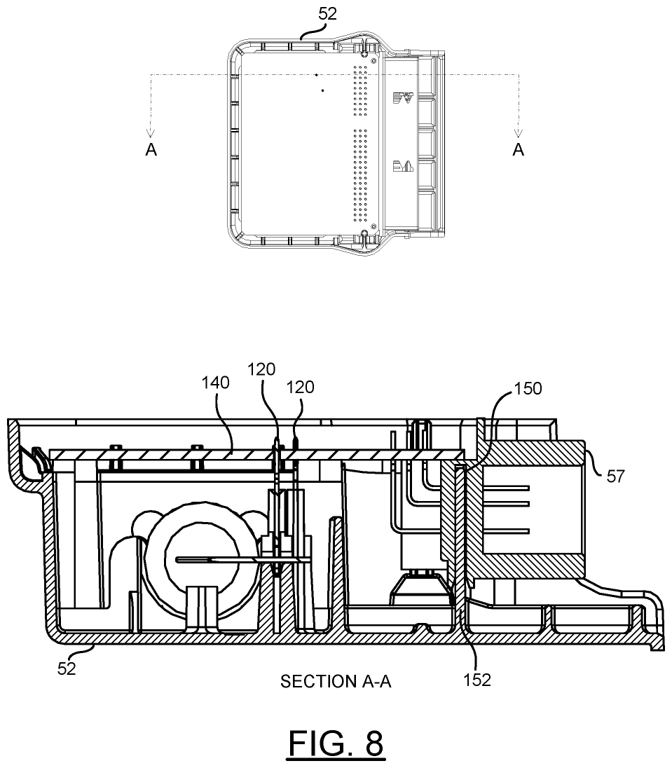

Referring to FIG. 7, a diagram is shown illustrating a portion of a housing with a component connected to flexible insulation displacement terminals in accordance with an example embodiment of the invention. In an example, the terminal support features 64a and 64b may comprise two towers separated by a gap. The two towers are generally configured to form an interference fit with the beams 108 and 112 of the flexible IDT 100. In an example, the two towers generally form U-shaped channels into which the outer edges of the second portion 107 of the flexible IDT 100 may be inserted. In an example, the barb features 126 may lock the second portion 107 of the flexible IDT 100 into the two towers of the terminal support features 64a and 64b. The gap between the two towers generally allows the cantilever beam 110 of the flexible IDT 100 to flex without being constrained or obstructed. In an example, the gap in each of the terminal support features 64a and 64b may further comprise a narrow lower portion that is configured to hold (support) the wires (or leads) 62a and 62b, respectively, of the component 60 while flexible IDTs 100 are pressed into the terminal support features 64a and 64b and onto the wires (or leads) 62a and 62b. The central edges of the beams 102 and 104 may be configured using conventional techniques to form a solid electrical contact with the wires (or leads) 62a and 62b.

Referring to FIG. 8, a diagram is shown illustrating an application of the flexible insulation displacement terminals in accordance with an example embodiment of the invention. In modules where performance during vibration is important (e.g., airbag control modules, etc.), the flexible IDT 100 may be rigidly attached to the upper housing 52 by the beams 108 and 112 creating an interference fit with an interior surface of the U-shaped channels formed by the two towers of the terminal support features of the upper housing 52. The press-fit pin 120 of the flexible IDT 100 may be rigidly attached to the printed circuit board 140. In modules where performance during vibration is important (e.g., airbag control modules, etc.), the connector assembly 57 may also be rigidly attached to the circuit board 140 and to the upper housing 52 with interference fits. In an example, the connector assembly 57 may have terminal pins that are press fit into the circuit board 140 and a channel feature 150 that forms an interference fit with a rib feature 152 of the upper housing 52.

In some embodiments, the connector assembly 57 may also be laser welded to the upper housing 52 (e.g., to provide a sealed ECU). The laser welding may alter the geometry of the upper housing 52 adding to the tolerance stack. The flexible IDT 100 generally allows the location of the connection of the printed circuit board 140 to the press-fit pin 120 to move (shift) relative to the upper housing 52, reducing the locations of the printed circuit board 140 that are constrained to the upper housing 52 in the same axis to the connector assembly 57. Despite the rigid attachments of the beam 108, the beam 112, and the press-fit pin 120, the cantilever beam 110 of the flexible IDT 100 is generally able to flex allowing the tolerance stack between components to be absorbed without deformation or fracture of the press-fit pin 120. Thus, the flexible IDT 100 may provide a more robust electronic control module.

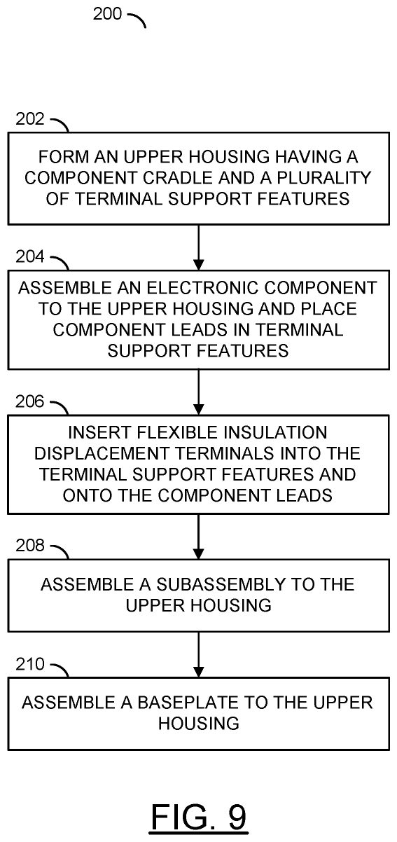

Referring to FIG. 9, a diagram is shown illustrating a method of assembly method in accordance with an example embodiment of the invention. A method (or process) 200 may be implemented to assemble an electronic control unit in accordance with an example embodiment of the invention. The method (or process) 200 may be implemented in a common production facility using typical assembly equipment and techniques. The method 200 generally comprises a step (or state) 202, a step (or state) 204, a step (or state) 206, a step (or state) 208, and a step (or state) 210.

In the step 202, an upper housing for an electronic control unit (ECU) may be formed. In various embodiments, the upper housing is generally formed having an interior mounting surface, a component cradle feature, and a plurality of terminal support features. The component cradle feature that is generally formed on the interior mounting surface of the upper housing. In an example, the component cradle feature may comprise one or more features extending along the interior mounting surface and defining an arcuate support for an electronic component. The plurality of terminal support features are generally formed on and extend perpendicularly from the interior mounting surface of the upper housing. In an example, each of plurality of terminal support features may comprise two towers separated by a gap. In an example, the two towers generally form U-shaped channels into which a flexible insulation displacement terminal (IDT) in accordance with an embodiment of the invention may be inserted.

In an example, the upper housing may be implemented as a non-conductive enclosure. In some embodiments, the upper housing may be configured to provide an environmentally sealed enclosure while mated with a lower housing (or baseplate) and a subassembly. In an example, the upper housing may be formed of a plastic or resin-based material. In various embodiments, the plastic or resin-based material may include, but is not limited to polyamide (NYLON), polybutylene terephthalate (PBT), polypropylene, polyethylene terephthalate (PET), acrylonitrile butadiene styrene (ABS), and/or various alloys and/or fillers of the resins. However, other materials may be implemented to meet the design criteria of a particular application. In various embodiments, the upper housing may be formed using various techniques including, but not limited to, casting, injection molding, and three-dimensional printing.

In the step 204, an electronic component may be assembled to the upper housing. In an example, the electronic component may be placed on the component cradle feature and secured within the upper housing. Each of a plurality of leads of the electronic component may be placed into a respective one of the plurality of terminal support features. In an example, the gap in each of the terminal support features may comprise a narrow lower portion that is configured to hold (support) the leads (or wires) of the electronic component while flexible IDTs are pressed into the terminal support features and onto the leads (or wires).

In the step 206, a plurality of flexible insulation displacement terminals (IDTs) are press fit into the plurality of terminal support features and onto the leads (or wires) to form electrical connections with the plurality of leads. Each of the plurality of flexible insulation displacement terminals comprises (i) a first portion comprising a first beam, a second beam, and a slot formed by a first central edge of the first beam and a second central edge of the second beam, (ii) a second portion comprising a third beam, a fourth beam, and a fifth beam, where the fourth beam is configured as a cantilever beam with an attached lower end and a distal end that is able to move between the third beam and the fifth beam, and (iii) a press-fit pin attached to an edge of the distal end of the cantilever beam. The slot in the first portion is generally configured to receive a respective lead (wire) of the plurality of leads and form a solid electrical connection with the respective lead.

In the step 208, a pre-assembled subassembly may be assembled to the upper housing. In an example, the pre-assembled subassembly may comprise a connector assembly assembled (attached) to a printed circuit board substrate of a circuit board assembly. In an example, a raw terminal carrier may be fed to a stitching station. The stitching station may stitch a row of terminal pins into the raw carrier. The stitching station may then pass the stitched carrier to a form station, where the form station forms an appropriate (e.g., 90 degrees, etc.) bend for the current row. The stitching and forming processes may be repeated until a number or rows of terminal pins desired have been stitched and formed to produced a completed terminal carrier assembly. The completed terminal carrier assembly may then be assembled to a connector shroud to form the connector assembly and the connector assembly assembled may be assembled to the printed circuit board substrate of the circuit board assembly.

In various embodiments, the terminal carrier generally includes a feature on each side (end) of the terminal carrier. The features are generally configured to align the terminal carrier with an interior surface of the upper housing. In various embodiments, a profile of the connector assembly and the features may be configured to align the circuit board assembly within the upper housing.

The press-fit pins of the plurality of flexible insulation displacement terminals may be inserted (or press fit) into plated holes (or vias) on the printed circuit board substrate of the printed circuit board assembly of the subassembly. Compliant pins generally need some insertion (or press fit) force in order to be assembled to plated holes in a printed circuit board (PCB). The terminal support features may be configured to support the press fit force of the compliant pin portion of the flexible insulation displacement terminals being assembled to the printed circuit board substrate of the printed circuit board assembly of the subassembly.

In some embodiments, the connector assembly may also be laser welded to the upper housing (e.g., to provide a sealed ECU). The laser welding may alter the geometry of the upper housing adding to a tolerance stack. The flexible insulation displacement terminals generally allow the location of the connections of the printed circuit board substrate to the press-fit pins to move (shift) relative to the upper housing, reducing locations of the printed circuit board substrate that are constrained to the upper housing in the same axis to the connector assembly. Despite the rigid attachments of the first beam, the second beam, and the press-fit pin of the flexible insulation displacement terminals, the cantilever beam of the flexible insulation displacement terminals is generally able to flex allowing the tolerance stack between components to be absorbed without deformation or fracture of the press-fit pins. Thus, the flexible insulation displacement terminals in accordance with an embodiment of the invention generally provide a more robust electronic control module.

In the step 210, a lower housing (or baseplate) may be assembled to the upper housing. In an example, the lower housing may be implemented as an electrically conductive baseplate. The lower housing may be configured to provide mechanical support, thermal cooling and electrical grounding for the electronic control unit. In various embodiments, the lower housing may comprise a die-cast Aluminum baseplate. In another example, the lower housing may be implemented as a stamped steel baseplate. Implementing the lower housing with a metallic material may aid in dissipating heat generated by circuitry within the electronic control unit. The lower housing may be configured to provide a mounting footprint for the electronic control unit. In an example, the lower housing may be implemented with an RCM8 mounting footprint to simplify testing. However, other footprints may be implemented to meet the design criteria of a particular application.

In various embodiments, a gasket or dispensed sealant material may be applied between any of the upper housing, the subassembly, and/or the lower housing. The gasket or sealant material may be selected to meet an automotive industry standard for sealing the electronic control unit to a particular environment. In various embodiments, the subassembly and/or the lower housing may be attached to the upper housing using a plurality of threaded fasteners.

The terms “may” and “generally” when used herein in conjunction with “is(are)” and verbs are meant to communicate the intention that the description is exemplary and believed to be broad enough to encompass both the specific examples presented in the disclosure as well as alternative examples that could be derived based on the disclosure. The terms “may” and “generally” as used herein should not be construed to necessarily imply the desirability or possibility of omitting a corresponding element.

The designations of various components, modules and/or circuits as “a”-“n”, when used herein, disclose either a singular component, module and/or circuit or a plurality of such components, modules and/or circuits, with the “n” designation applied to mean any particular integer number. Different components, modules and/or circuits that each have instances (or occurrences) with designations of “a”-“n” may indicate that the different components, modules and/or circuits may have a matching number of instances or a different number of instances. The instance designated “a” may represent a first of a plurality of instances and the instance “n” may refer to a last of a plurality of instances, while not implying a particular number of instances.

While the invention has been particularly shown and described with reference to embodiments thereof, it will be understood by those skilled in the art that various changes in form and details may be made without departing from the scope of the invention.

1. An insulation displacement terminal comprising:
a first portion comprising a first beam and a second beam, wherein a slot is formed by a first central edge of the first beam and a second central edge of the second beam;
a second portion comprising a third beam, a fourth beam, and a fifth beam, wherein the fourth beam is configured as a cantilever beam with an attached lower end and a distal end that is able to move between the third beam and the fourth beam; and
a press-fit pin attached to an edge of the distal end of the fourth beam.

2. The insulation displacement terminal according to claim 1, wherein the second portion is wider than the first portion.

3. The insulation displacement terminal according to claim 1, wherein the distal end of the fourth beam is wider than the attached lower end of the fourth beam.

4. The insulation displacement terminal according to claim 1, wherein:
the second portion has a first outer edge comprising a first barb feature and a first shoulder feature and a second outer edge comprising a second barb feature and a second shoulder feature.

5. The insulation displacement terminal according to claim 4, wherein the first barb feature and the second barb feature allow the insulation displacement terminal to rigidly attach to a terminal support feature of a housing of an electronic control module.

6. The insulation displacement terminal according to claim 5, wherein the first shoulder feature and the second shoulder feature allow the insulation displacement terminal to be inserted to a predetermined depth within the terminal support feature of the housing of the electronic control module.

7. The insulation displacement terminal according to claim 1, wherein the fourth beam further comprises one or more holes located adjacent to the edge of the distal end of the fourth beam.

8. The insulation displacement terminal according to claim 1, wherein the slot formed by the first central edge of the first beam and the second central edge of the second beam has an approximate width that is smaller than a diameter of a lead with which the insulation displacement terminal forms an electrical connection.

9. An apparatus comprising:
a housing having an inner mounting surface;
a component cradle formed on said inner mounting surface of said housing;
an electronic component mounted within said component cradle, said electronic component having a plurality of leads;
a plurality of terminal support features formed on said inner mounting surface of said housing adjacent to said component cradle, wherein each of said terminal support features comprises two towers separated by a gap and the gap comprises an open upper end and a narrow lower portion that is configured to receive one of said plurality of leads of said electronic component; and
a plurality of flexible insulation displacement terminals, wherein each of said plurality of flexible insulation displacement terminals comprises a first portion comprising a first beam and a second beam, wherein a slot is formed by a first central edge of the first beam and a second central edge of the second beam, the slot has an approximate width that is smaller than a diameter of said one of said plurality of leads, a second portion comprising a third beam, a fourth beam, and a fifth beam, wherein the fourth beam is configured as a cantilever beam with an attached lower end and a distal end that is able to move between the third beam and the fifth beam, and a press-fit pin attached to an edge of the distal end of the cantilever beam, and each of said flexible insulation displacement terminals is pressed into a respective one of said plurality of terminal support features and forms an electrical connection with said slot receiving one of said plurality of leads.

10. The apparatus according to claim 9, wherein said electronic component comprises a charge storage device.

11. The apparatus according to claim 9, wherein the flexible insulation displacement terminals are configured to electrically connect the electronic component mounted within the component cradle to a printed circuit board substrate.

12. The apparatus according to claim 11, wherein said terminal support features are formed on said inner mounting surface of said housing such that said plurality of leads connecting the electronic component to the flexible insulation displacement terminals form a right angle bend.

13. A method for assembling an electronic control unit, comprising the steps of:
forming a housing comprising an inner mounting surface, a component cradle formed on the inner mounting surface of the housing, and a plurality of terminal support features formed on the inner mounting surface of the housing;
placing an electronic component on the component cradle and placing a plurality of leads of the electronic component in the plurality of terminal support features; and
press fitting a plurality of flexible insulation displacement terminals in said plurality of terminal support features to form electrical connections with said plurality of leads, wherein each of said plurality of flexible insulation displacement terminals comprises a first portion comprising a first beam and a second beam, wherein a slot is formed by a first central edge of the first beam and a second central edge of the second beam, a second portion comprising a third beam, a fourth beam, and a fifth beam, wherein the fourth beam is configured as a cantilever beam with an attached lower end and a distal end that is able to move between the third beam and the fifth beam, and a press-fit pin attached to an edge of the distal end of the cantilever beam.

14. The method according to claim 13, further comprising:
attaching a circuit board assembly with an attached connector assembly to the housing such that the press-fit pin of each of the plurality of flexible insulation displacement terminals is press fit into a corresponding via of the circuit board assembly.

15. The method according to claim 14, further comprising:
laser welding the connector assembly to the housing;
applying at least one of a gasket and a sealant material to the housing; and
assembling a baseplate to the housing.
